(19) United States
(12) Patent Application Publication
(10) Pub. No.: US 2014/0373919 A1
(43) Pub. Date: Dec. 25, 2014

(54) PHOTOVOLTAIC CELL AND MANUFACTURING PROCESS

(71) Applicant: COMMISSARIAT À L'ENERGIE ATOMIQUE ET AUX ENERGIES ALTERNATIVES, Paris (FR)

(72) Inventors: Thibaut Desrues, Mont Saint-Aignan (FR); Sylvain De Vecchi, Chambery (FR); Florent Souche, Saint-Laurent-du-Pont (FR)

(21) Appl. No.: 14/370,857

(22) PCT Filed: Jan. 3, 2013
(86) PCT No.: PCT/FR2013/000006

§ 371 Date: Jul. 7, 2014

(30) Foreign Application Priority Data
Jan. 5, 2012 (FR) 1200037

(51) Int. Cl. H01L 31/0376; H01L 31/02; H01L 31/074; H01L 31/18

(52) U.S. Cl. CPC H01L 31/03762; H01L 31/1804; H01L 31/02008; H01L 31/074
USPC 136/258; 438/96

(57) ABSTRACT

A photovoltaic cell including a semiconductor substrate of a first conductivity type provided with a main surface, a first layer made from amorphous semiconductor material of first conductivity type in contact with the main surface of the substrate, a first electric contact formed on the first amorphous layer, a second layer of amorphous semiconductor material of a second conductivity type in contact with the main surface of the substrate, a second electric contact formed on the second amorphous layer and an electrically insulating layer, a cell wherein the electrically insulating layer is formed completely on the first amorphous layer and the first and second contacts extend on the electrically insulating layer.

### BACKGROUND OF THE INVENTION

The invention relates to a photovoltaic cell.

The invention also relates to a method for producing a photovoltaic cell.

### State of the Art

In the field of photovoltaic cells, research is mainly focused on improving the conversion efficiency of the cell, for example by reducing recombination of photogenerated charge carriers and/or by reducing resistive losses, and on simplification of the method for producing photovoltaic cells.

In conventional manner, a photovoltaic cell is formed by a diode, for example a p/n junction made from a semiconductor material such as silicon. The diode then comprises an area doped by a p-type impurity, for example boron, and an area doped by an n-type impurity, for example phosphorus.

In order to improve the conversion efficiency of photovoltaic cells, different architectures have been proposed.

In a first instance, silicon heterojunction cells combine a crystalline silicon substrate, c-Si, associated with ultra-thin layers of amorphous silicon a-Si : H, deposited to form junctions with the crystalline silicon. The bandgap energy of the a-Si:H (1.5 eV<E_{G}<1.9 eV) is higher than that of the c-Si (1.12 eV). The first developments of heterojunction cells were made on structures where only the emitter was formed by an a-Si : H film, with interesting efficiencies.

Research has also been carried out in order to improve collection of the electron-hole pairs, the Back Surface Field (BSF) configuration being advantageous. This field improves the electrical characteristics of the solar cell, in particularly the open circuit voltage by reduction of the dark current. The carriers which have in fact become minority after they have been injected into the back area move away from the depletion area. The back surface field (BSF) propels them towards the junction.

Finally, new architectures have been proposed in order to reduce the collection surface, the front surface. Rear Contact Cells (RCC) enable emitter and BSF areas to be located on the back surface thereby preventing shadowing due to metallization of the front surface. Heterojunction cell architectures, and particularly double heterojunction cells with an emitter and a BSF made from a-Si:H, on the back surface, are described in the documents U.S. Pat. No. 7,199,395 and US 2004/0043528.

These architectures are moreover relatively long to implement and present risks of poor efficiency.

The spaces and overlaps of the different layers of the photovoltaic cell do in fact impose tolerances in the geometry of the masks and in the alignment between depositions to prevent short-circuiting. For example, a good alignment is required between the different levels of layers made on the substrate. Thus, the more complex the geometry of the back surface, the more location steps it requires. A tolerance is added at each location step, which increases the width of the device and can reduce its performances. A requirement therefore remains to develop a photovoltaic cell of simple back surface geometry in order to obtain high conversion efficiencies.

### OBJECT OF THE INVENTION

The object of the invention is to provide a photovoltaic cell having a structure that is compact while at the same time facilitating formation of the contacts in order to keep good efficiencies.

It is a further object of the invention to provide a method for producing a photovoltaic cell that is robust, easy to implement and that enables the number of technological steps to be reduced.

This object tends to be achieved by the appended claims.

### BRIEF DESCRIPTION OF THE DRAWINGS

Other advantages and features will become more clearly apparent from the following description of particular embodiments of the invention given for non-restrictive example purposes only and represented in the appended drawings, in which:

FIG. 1 represents a photovoltaic cell, in schematic manner, in cross-section,

FIGS. 2, 3 and 4 represent a photovoltaic cell in the course of fabrication, in schematic manner, in cross-section,

FIG. 5 represents a schematic top view of the photovoltaic cell.

### DESCRIPTION OF A PREFERRED EMBODIMENT OF THE INVENTION

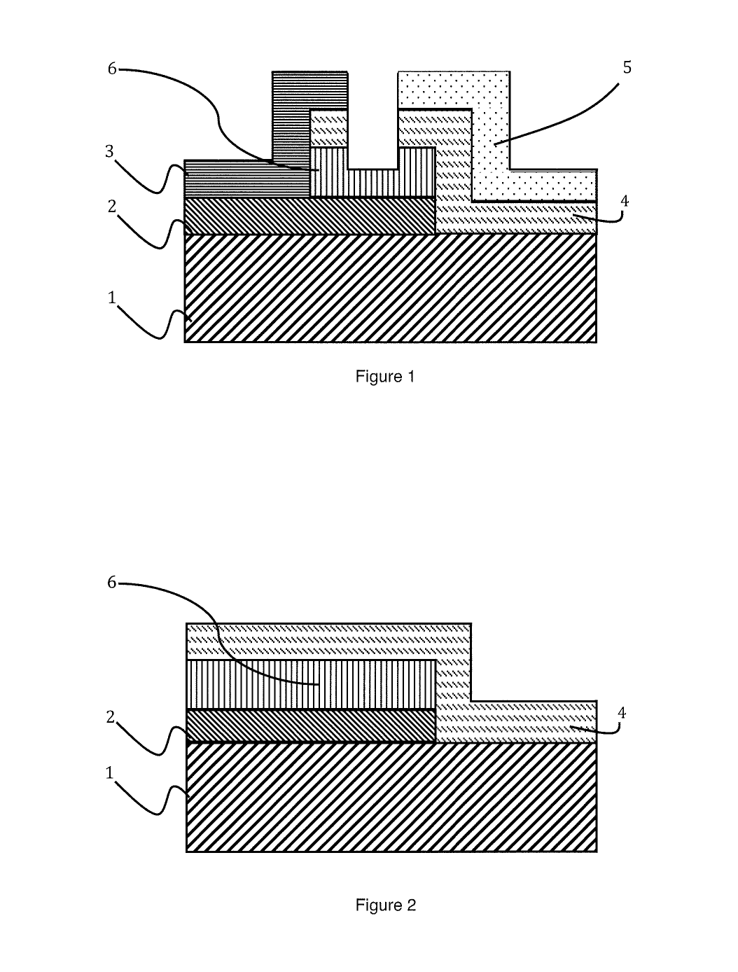

As illustrated in FIG. 1, the photovoltaic cell comprises a substrate 1 of a first conductivity type provided with a main surface. Substrate 1 is crystalline, i.e. single-crystalline or polycrystalline. Substrate 1 is formed from a semi-conductor material, for example a material of type IV, such as Si, Ge, an alloy of these materials, a material of type III-V or II-VI. It comprises, on its main surface, a first layer made from amorphous semiconductor of a first conductivity type 2 and a second layer made from amorphous conductor of a second conductivity type 4, both in contact with the main surface of substrate 1. The first and second amorphous layers are electrically connected to substrate 1 so as to form a junction with the substrate and/or to allow the passage of charge carriers between the amorphous layers and the substrate. The first and/or second amorphous layers can thus have an interface with the substrate. In preferential manner, the interfaces are abrupt.

This structure is called heterojunction photovoltaic cell as the two materials which form this junction have a different bandgap energy (E_{G}).

The second type of conductivity is the opposite of the first type of conductivity.

The heterojunction is preferably between an amorphous material and an identical monocrystalline or polycrystalline material. Advantageously, the heterojunction is of a-Si:H/c-Si type. The substrate may present a passivation layer such as for example a layer of thermal SiO₂, Al₂O₃, or any material able to passivate the surface of the c-Si. The properties of the passivation layer are configured so as to preserve the junction between the substrate and the amorphous layer.

The heterojunction is for example made from silicon or from any other suitable material, for example a junction such as CdS/CdTe or having a base formed by organic material such as PEDOT/PSS (Poly(3,4-ethylene-dioxythiophene) poly(styrenesulfonate)). Copper Indium diselenide or gallium arsenide can also be used.

The first amorphous layer of the first conductivity type is preferably made from doped amorphous silicon. First amorphous layer 2 is preferably made from n-doped amorphous silicon, a-Si:H i/n. The first amorphous layer preferably enables a back surface field to be formed.

The second amorphous layer of the second conductivity type 4 is preferably p-doped amorphous silicon, a-Si:H i/p. The second amorphous layer forms a p/n junction with the substrate, which enables the carrier current generated in the photovoltaic cell to be recovered. This second amorphous layer can also be called emitter.

On its main surface, the photovoltaic cell also comprises a first electric contact 3 formed on the first layer and a second electric contact 5 formed on the second layer. The electric contact materials are electrically conductive, for example aluminium and/or ITO. In preferential manner, the interfaces between the electric contacts and the amorphous materials are abrupt or formed by means of a silicide.

The photovoltaic cell also comprises an electrically insulating layer 6 on its main surface. The material of electrically insulating layer 6 is for example a silicon oxide, a silicon nitride, a silicon carbide or a material of a-Si:H type which may be stoichiometric or not. The material of electrically insulating layer 6 can also be a stack or a mixture of the latter materials. In preferential manner, layer 6 is formed by a stack of a layer poor in Si covered by a layer rich in Si. For example, it is possible to have a first layer of nitride poor in silicon obtained by means of a NH₃/SiH₄ gas flow with a ratio comprised between 2 and 10 covered by a second layer of nitride rich in silicon obtained with a gas ratio close to 1, typically less than 2. Layer 6 can for example be made from Al₂O₃ or a stack of silicon nitride or oxide, with a first protective layer poor in Si covered by an absorbent layer rich in Si. This stack presents the advantage of being easy to etch. Layer 6 can for example be produced by plasma-enhanced chemical vapor deposition PECVD, low pressure chemical vapor deposition LPCVD, screen printing or inkjet.

Electrically insulating layer 6 is formed totally on first amorphous layer 2. Electrically insulating layer 6 can have an interface with first amorphous layer 2. It does not have an interface with substrate 1. The back surface field (BSF) effect and the efficiency are thus increased. In addition, the surface of second amorphous layer 4 is left free for contact 5. Advantageously, a better compactness of the photovoltaic cell is obtained.

First and second contacts 3 and 5 respectively extend on the first and second amorphous layers, continuing on electrically insulating layer 6 to increase the active surface of the contacts on the main surface without increasing the risk of short-circuiting. This architecture easily enables resistive losses to be reduced. Advantageously, the other opposite main surface is free enabling the light radiation collection surface to be optimized.

First electric contact 3 and second electric contact 5 are electrically dissociated. The contacts do not have an interface with the substrate to prevent short-circuiting and they are preferably formed on the same surface of electrically insulating layer 6.

In a preferred embodiment, a part of second amorphous layer 4 covers electrically insulating layer 6 and this electrically insulating layer 6 covers a part of first amorphous layer 2. Electrically insulating layer 6 enables amorphous layers 2 and 4 of different conductivity types to be insulated. The performances of the photovoltaic cell are thus improved and the lifetime of the photovoltaic cells is increased.

Second amorphous layer 4, electrically connected to substrate 1, is totally covered by the electric contacts and more particularly by second electric contact 5. It has been observed that complete or almost complete covering of second layer 4 by second contact 5 enables the electric performances of the photovoltaic cell to be increased, even if the additional contact surface has a negligible effect on transportation of the charges. Furthermore, as second amorphous layer 4 is totally covered by electric contact 5, layer 4 is protected from the outside environment, which results in its lifetime being increased.

What is meant by totally covered surface is the surface of layer 4 which has an interface with substrate 1. This surface has to be more than 95% and advantageously 100% covered. The surface of layer 4 which has an interface with electrically insulating layer 6 can on the other hand be only partially covered by contact 5.

In an embodiment that is able to be combined with the previous embodiments, the main surface of substrate 1 is completely covered by first amorphous layer 2 and second amorphous layer 4. This enables the efficiency of the cell to be increased by using the whole of the usable main surface to recover the photogenerated current or form the back surface field. According to a preferred embodiment, only the lateral surfaces of amorphous layers 2 and 4 are in contact. In this architecture, amorphous layers 2 and 4, connected to substrate 1, form a p/n junction. According to one embodiment, to prevent too large leaks between layers 2 and 4, several solutions are possible. A stack of a first non-doped or very lightly doped thin layer (1 to 10 nm) covered by a doped layer can be used for layer 4. It can also be provided to locally modify layer 2 in proximity to layer 4 by doping it (p or hydrogen) to make it locally insulating. It is also possible to modify layer 4 locally.

What is meant by completely covered surface is a surface that is more than 95% and advantageously 100% covered.

In a particular embodiment that is able to be combined with the previous embodiments, the structure comprises, in a perpendicular direction to the main surface, a stack successively comprising substrate 1, first amorphous layer 2, electrically insulating layer 6, second amorphous layer 4, and electric contact 5. Contact 5 and first layer 2 are separated, perpendicularly to the substrate, by electrically insulating layer 6 and second layer 4. The offset between contact 5 and first layer 2 is defined by the thicknesses of second layer 4 and of electrically insulating layer 6, and not by means of one or more photolithography steps, which enables a compact architecture to be had.

This further enables a better overlap of the different layers while at the same time ensuring maximum covering of contacts 3 and 5 on amorphous layers 2 and 4. This reduces or even eliminates the risks of direct contact between first amorphous layer 2 and the electric contact of second amorphous layer 5.

Electric contacts 3 and 5 extend above electrically insulating layer 6 and are electrically dissociated. In a particular embodiment able to be combined with the previous embodiments, an electrically insulating groove exists between the two contacts 3 and 5. The insulating groove is defined between contacts 3 and 5 and it preferably extends inside second layer 4 to reduce the risks of leakage when the latter has a part which is in electric contact with first contact 3. In even more preferential manner, this groove prevents a possible accumulation of conducting dust during the method for producing or during the lifetime of the photovoltaic cell, which would place the contact of first amorphous layer 3 in electric contact with second contact 5.

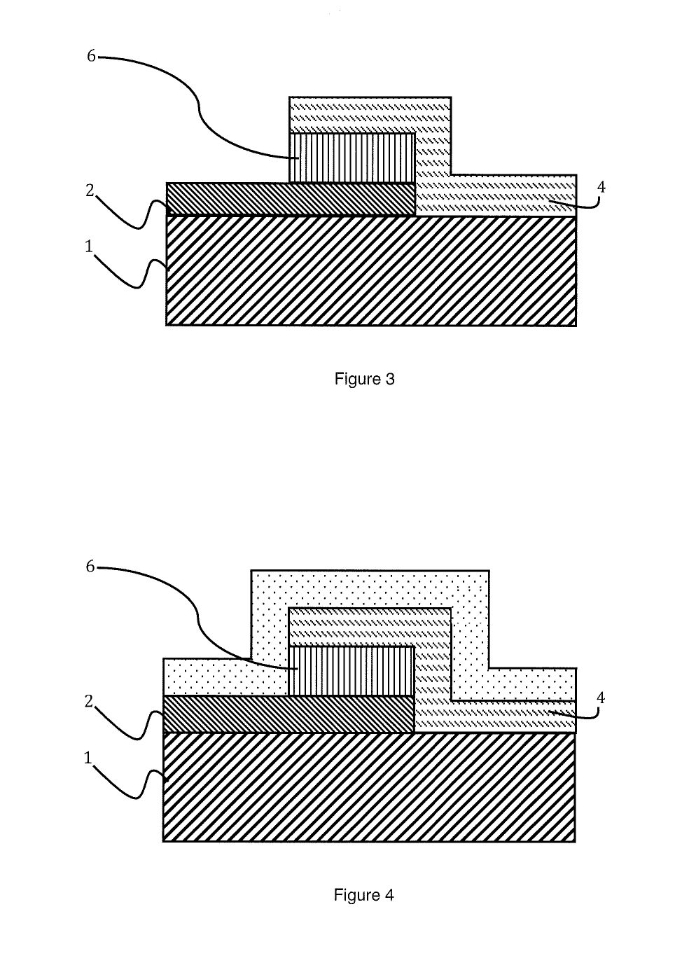

In a particular embodiment, the photovoltaic cell is formed in the following manner. As illustrated in FIG. 2, a substrate 1 comprising a layer of semiconductor material of a first conductivity type has to be provided. Substrate 1 is partially covered by a first pattern comprising a first amorphous layer 2 of first conductivity type and an electrically insulating layer 6. Electrically insulating layer 6 is separated from substrate 1 by first amorphous layer 2. Substrate 1 and the first pattern are covered by a second amorphous layer 4 of a second conductivity type.

To obtain this type of substrate, support substrate 1 can preferably be covered by an amorphous layer 2 of first conductivity type. Layer 2 of first conductivity type is deposited by any suitable technique and is for example a layer of n-doped a-Si:H. First layer 2 can be deposited by plasma enhanced chemical vapor deposition PECVD, low pressure chemical vapor deposition LPCVD or atmospheric pressure chemical vapor deposition APCVD for example. The layer of first conductivity type 2 preferably presents a thickness comprised between 5 nm and 50 nm after deposition. This thickness range advantageously enables the surface to be correctly passivated while avoiding resistive losses in the layers.

This first amorphous layer 2 is covered by an electrically insulating layer 6. First amorphous layer 2 and electrically insulating layer 6 preferably have the same pattern and are perfectly aligned, i.e. the lateral surfaces 2 and 6 are in the continuity of one another.

The material of electrically insulating layer 6 is preferably obtained by means of plasma enhanced chemical vapor deposition. Atomic layer deposition or plasma enhanced atomic layer deposition techniques (ALD, PEALD) can also be used. It is also possible to deposit materials such as Al₂O₃, the choice being made according to the structure and the stresses present.

Electrically insulating layer 6 preferably has a thickness comprised between 10 nm and 2000 nm. This thickness range advantageously enables a good trade-off to be obtained between the thickness, the deposition time and the insulating properties of the layer.

Electrically insulating layer 6 and first amorphous layer 2 are then etched by means of the same etching mask so as to self-align the pattern formed in electrically insulating layer 6 and the pattern formed in first layer 2. The substrate is then partially covered by the same pattern.

A part of the surface of first layer 2 and/or of electrically insulating layer 6 can be etched, preferably by laser irradiation and/or by wet etching for example.

Amorphous layer 4 of second conductivity type is then deposited by any suitable technique, it is for example a layer of p-doped a-Si:H deposited by plasma-enhanced chemical vapor deposition PECVD, low pressure chemical vapor deposition LPCVD or atmospheric pressure chemical vapor deposition APCVD for example. The amorphous layer of second conductivity type 4 referably presents a thickness comprised between 5 nm and 50 nm after deposition. This thickness range enables the surface to be correctly passivated while preventing resistive losses in the layers. Second layer 4 is deposited in non-selective manner and covers the substrate and the first pattern.

Layers 2 and 4 can advantageously be formed by a stack of two layers. The first layer, in contact with the substrate, is not doped or is very lightly doped and passivates the interface. An efficient passivation can be obtained by means of a first layer having a thickness comprised between 1 and 10 nm. The second layer is doped and provides the electric field necessary for carrier collection.

Second amorphous layer 4 and the first pattern are then partially etched to release a part of first amorphous layer 2, substrate 1 being left covered by second amorphous layer 4, as illustrated in FIG. 3. Etching of second amorphous layer 4 and of electrically insulating layer 6 is performed above first amorphous layer 2, at the level of the left part as illustrated in FIG. 3. Etching stops on amorphous layer 2 and defines a bump of electrically insulating material extending vertically between the two amorphous layers. A part of the surface of second amorphous layer 4 and of electrically insulating layer 6 can then be etched preferably by laser irradiation and/or by wet etching for example.

Afterwards, as illustrated in FIG. 4, a contact of first amorphous layer 3 and a contact of second amorphous layer 5 are formed by means of an electrically conducting material, the two contacts partially covering electrically insulating layer 6 and being electrically dissociated.

In a particular embodiment, the contacts are formed by deposition of the electrically conducting material on first amorphous layer 2 and second amorphous layer 4.

Electrically conducting contacts 3 and/or 5 are deposited by any suitable technique, preferably by spraying, electrochemical deposition, screen printing, evaporation, or inkjet. The thickness of the electric contacts is for example comprised between 1 μm and 50 μm after deposition in order not to cause partial or total depletions of the doped areas or to give rise to series resistance problems.

The electrically conducting material 6 is etched to form the two contacts 3 and 5. Second amorphous layer 4 can then be etched above electrically insulating layer 6 in the extension of the hole formed in the electrically conducting material to release a part of electrically insulating layer 6, so as to electrically dissociate the two contacts 3 and 5 and possibly two parts of second layer 4. Layer 4 is advantageously etched so as to reduce the electric losses between contacts 3 and 5. However, on account of its low conductivity, it can be partially etched or not etched.

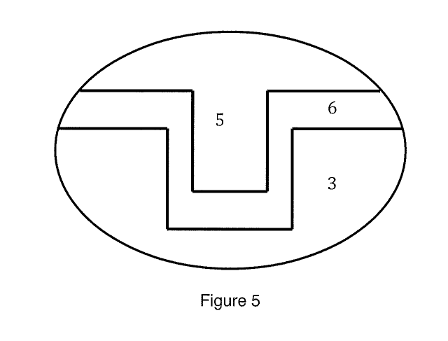

According to a preferred embodiment and as represented in top view in FIG. 5, contacts 3 and 5 present a crenelated shape engaging in one another, the contacts being separated by layer 6.

Etching of the material of electrically insulating layer 6 is performed above second layer 4. When etching is performed, second layer 4 can be eliminated so as to prevent contact 3 from being associated with the material forming second layer 4. This configuration depends on the extent of the area to be etched and on its position above electrically insulating layer 6.

In preferential manner, electrically insulating layer 6 comprises: a first absorbent layer (rich in silicon for example) and a second protective layer (poor in silicon for example), the protective layer being in contact with the amorphous layer of first conductivity 2. Laser irradiation then opens the absorbent layer, rich in Si, but does not damage layer 2 due to the presence of the protective layer. The latter is then easily etched by means of a wet etching process.

The absorbent layer can easily be patterned by laser irradiation.

The absorbent layer will preferably be etched by laser irradiation and the protective layer by chemical etching.

In preferential manner, laser etching removes a part of the absorbent layer separating the absorbent layer in the middle thereof into two non-contacted parts and leaving a part of the protective layer free. The protective layer thus acts as laser irradiation etch stop layer. A trench is thus formed in simple manner in electrically insulating layer 6.

In the case where etching of electrically insulating layer 6 extends up to first amorphous layer 2, the electrically insulating layer being totally etched in its thickness, two elementary patterns of electrically insulating layer 6 exist one of which is used by the stack formed by substrate 1/first amorphous layer 2/electrically insulating layer 6/second amorphous layer 4/electric contact 5. In preferential manner, electrically insulating layer 6 is not completely etched in order to leave a space between contacts 3 and 5 and to protect layer 2.

Etching of second amorphous layer 4, of the electrically conducting material and/or possibly of a part of electrically insulating layer 6 can be performed in a single step preferably by laser irradiation.

As etching is performed above electrically insulating layer 6, it simply suffices to align the laser above this layer. One of the lateral surfaces of second amorphous layer 4 and of contact 5 are thus self-aligned to have complete or almost complete covering of second layer 4 by contact 5.

Contacts 3 and 5 are separated by the same distance above electrically insulating layer 6. There is therefore no short-circuit between contacts 3 and 5.

The photovoltaic cell thus has low tolerance values to the technological steps requiring alignments and can achieve high efficiencies while at the same time limiting the risks of short-circuits.

In order for the photovoltaic cell to be able to be implemented by means of a fabrication method that is robust, easy to implement and that ensures throughputs compatible with industrial production, it is advantageous to perform etching by laser irradiation. Laser irradiation will preferably be performed with a wavelength of less than 600 nm, a fluence comprised between 0.01 J/cm2 and 10 J/cm2, a frequency comprised between 10 kHz and 10,000 kHz and a pitch comprised between 1 μm and 100 μm.

Preferably, laser irradiation is used to etch a part of electrically insulating layer 6, a part of second amorphous layer 4 and electric contacts 3 and 5 in a single step.

In another embodiment, at least a part of the etchings can be performed by a wet etching process. The duration is 2 minutes and the etching solution is HF at 2%.

The electrically insulating layer performs the function of a mask, which enables the method to be simplified by reducing the number of steps necessary for fabricating photovoltaic cells and using techniques that are easily industrializable, such as laser irradiation or chemical etching, unlike more conventional techniques which are more difficult to industrialize, such as photolithography, metallic masks or screen printing for example.

Layers 2 and 4 have been presented as amorphous layers to form a double heterojunction cell, but another crystalline structure can be used for one and/or for the other. The person skilled in the art will keep in mind the fact that the additional steps of location of the different layers described above are possible, for example to modify the extent of second layer 4 on electrically insulating layer 6, or to form a spacer on the edges of the pattern made from materials 2 and 6.

According to a particular embodiment, layers 2 and 4 can be inverted, for example if the area of layer 2 covered by layer 6 is very narrow, less than 10 μm.

1-12. (canceled)

13. A photovoltaic cell comprising:
a semiconductor substrate of a first conductivity type provided with a main surface,
a first layer of amorphous semiconductor material of the first conductivity type in contact with the main surface of the substrate,
a first electric contact formed on the first amorphous layer,
a second layer of amorphous semiconductor material of a second conductivity type in contact with the main surface of the substrate,
a second electric contact formed on the second amorphous layer and
an electrically insulating layer,
wherein the electrically insulating layer is formed completely on the first amorphous layer and comprises a first absorbent layer and a second protective layer,
and wherein the first and second contacts extend on the electrically insulating layer.

14. The photovoltaic cell according to claim 13, wherein the second amorphous layer is totally covered by the electric contact and covers the insulating layer.

15. The photovoltaic cell according to claim 13, wherein the second amorphous layer, electrically connected to the substrate, is totally covered by the second electric contact.

16. The photovoltaic cell according to claim 13, wherein the main surface of the substrate is completely covered by the first amorphous layer and the second amorphous layer.

17. The photovoltaic cell according to claim 13, wherein the absorbent layer of the electrically insulating layer is separated in its middle into two non-contacted parts, leaving a part of the protective layer free.

18. The photovoltaic cell according to claim 13, said cell comprising at least one stack successively comprising the substrate, the first amorphous layer, the electrically insulating layer, the second amorphous layer, and one of the electric contacts in a perpendicular direction to the main surface.

19. The photovoltaic cell according to claim 13, wherein the protective layer of the electrically insulating layer is in contact with the amorphous layer of the first conductivity type and wherein the absorbent layer covers the protective layer.

20. The photovoltaic cell according to claim 19, wherein the absorbent layer is a layer rich in silicon and wherein the protective layer is a layer poor in silicon.

21. The photovoltaic cell according to claim 13, wherein the first electric contact and the second electric contact are separated by an electrically insulating groove and wherein the groove extends inside the second amorphous layer.

22. The photovoltaic cell according to claim 13, wherein:
the electrically insulating layer is formed completely on the first amorphous layer, the first electric contact covering the first amorphous layer and the electrically insulating layer,
the second amorphous layer is totally covered by the second electric contact.

23. A method for producing a photovoltaic cell, comprising the following steps:
providing a substrate comprising a layer of semiconductor material of a first conductivity type, the substrate being partially covered by a first pattern comprising:
a first amorphous layer of the first conductivity type,
and an electrically insulating layer separated from the substrate by the first amorphous layer, said electrically insulating layer comprising a protective layer and an absorbent layer,
the substrate and the first pattern being covered by a second amorphous layer of a second conductivity type,
partially etching the second amorphous layer and the first pattern to release a part of the first amorphous layer, a part of the substrate being left covered by the second amorphous layer, said etching being performed by laser irradiation and only removing a part of the absorbent layer of the electrically insulating layer, separating the absorbent layer into two non-contacted parts and leaving a part of the protective layer free,
forming a first contact of the first amorphous layer and a second contact of the second amorphous layer with an electrically conducting material, the two contacts partially covering the electrically insulating layer and being electrically dissociated.

24. The method according to claim 23, wherein the first and second contacts are formed by:
deposition of the electrically conducting material on the first and second amorphous layers,
etching of the electrically conducting material and of the second amorphous layer on the electrically insulating layer to release a part of the electrically insulating layer and to electrically dissociate the two contacts.
